(19) United States
(12) Patent Application Publication
(10) Pub. No.: US 2004/0168313 A1
(43) Pub. Date: Sep. 2, 2004

(54) Process to manufacture microwave components using hard anodised aluminum

(76) Inventor: Hans Magnusson, Kallered (SE)

Correspondence Address: Orum & Roth, 53 West Jackson Boulevard, Chicago, IL, 60604, US

(21) Appl. No.: 10/480,518

(22) PCT Filed: Jun. 14, 2002
(86) PCT No.: PCT/SE02/01162

(30) Foreign Application Priority Data
Jun. 14, 2001 (SE) 0102133-6

(51) Int. Cl. H01P 11/00; H05K 3/02

(52) U.S. Cl. 29/847; 29/846; 29/600

(57) ABSTRACT

The invention relates to a process for reducing the dimension and dramatically reducing the manufacturing cost, and of increasing the reliability of microwave components such as antennae (2), power dividers, filters, directional couplers and other types of integrated line networks, by producing a surface layer with a high dielectric constant on an aluminum substrate by hard anodization in combination with flat conductor technology.

The present invention relates to a process for the manufacture of microwave components, such as antennae, power dividers, filters, directional couplers and other integrated line networks.

Within telecommunications and related applications, there is a major need to reduce the dimensions of certain components, to reduce the manufacturing cost and to increase the reliability. This is achieved by a manufacturing process in accordance with the invention.

The dimensions of microwave components such as those referred to above are in a direct relationship with the actual wavelength and for that reason are determined by it in many cases. It is a well-known fact that the dimensions can be reduced by the introduction of a dielectric with a given dielectric ratio at the actual wavelength, known as the dielectric constant and designated with the Greek letter ε, epsilon. The dimensions can then be reduced to the ratio

$$\frac{1}{\underline{√ ϵ}}$$

If the dielectric constant is 4.0, for example, this means that the dimensions can be reduced to one half. A higher dielectric constant is often required to further reduce the dimensions, in which case ceramic materials are recommended. These are expensive, however, and difficult to work and combine with other materials, such as aluminium, due to the major difference in linear expansion.

In the present invention the dielectric is obtained with the dielectric constant of 9-36, which consequently reduces the dimensions within the range from one third to one sixth.

The principal object of the present invention is to reduce the dimensions of microwave components by the provision of a dielectric with a high dielectric constant by simple and inexpensive means.

The aforementioned object is achieved by a method in accordance with the present invention, which is characterized essentially in that use is made of a dielectric consisting of aluminium oxide, which is produced by the hard anodization of aluminium.

The procedure for the invention thus utilizes an electrolytic method to oxidize aluminium, in conjunction with which the formed aluminium oxide is used as a dielectric, and, where appropriate, the dielectric constant is further increased by so-called doping.

The electrical function is achieved by the application of a metal coating to the formed oxide layer, for example with copper, and by the subsequent etching of the actual conductor pattern.

Aluminium is a material that is easy to work and is available in many forms, for example rolled, extruded and cast. The metal can be oxidized by electrolytic means, in conjunction with which aluminium oxide, Al₂O₃, is formed. Aluminium oxide has a dielectric constant of ca. 9. One requirement for the suitability of aluminium oxide for use as a dielectric in applications of the kind in question is that the oxide layer must be sufficiently thick. A thickness of at least ca. 50 μm, but preferably 80-100 μm, is necessary. Aluminium oxide layers of this thickness are obtained with the help of so-called hard anodization, in conjunction with which use is made of an electrolyte consisting of dilute sulphuric acid, which is kept chilled to ca. 5° C.

By introducing into the electrolyte a dispersion consisting of a substance with a very high dielectric constant, this substance can be incorporated into the layer and can significantly increase the dielectric constant in the layer. A process of this kind is referred to as doping. Barium titanate is an example of a substance with a very high dielectric constant. Doping with barium titanate has been found to give a dielectric constant of ca. 20.

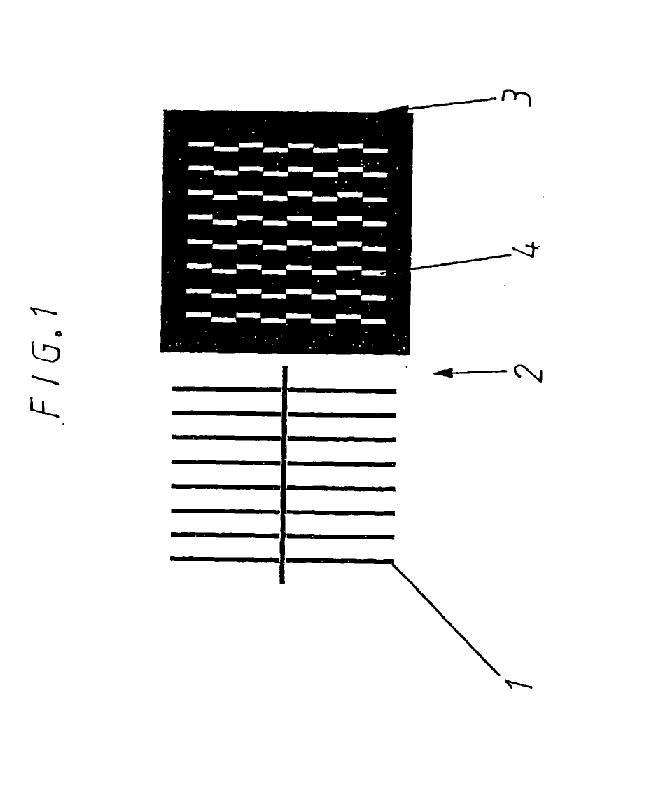

The invention is described below as a number of preferred illustrative embodiments, in conjunction with which reference is made to the accompanying FIG. 1. Illustrated in the aforementioned FIG. 1 is an example of a so-called slot antenna 2 in flat conductor technology.

The invention is not restricted to what is described above and indicated in the claims, but can be varied within the scope of the Patent Claims without departing from the idea of invention.

### EXAMPLE 1

An aluminium sheet with the dimensions 2×50×50 mm was hard anodized to a thickness of ca. 100 μm. The oxide layer was applied by vaporization with copper to a thickness of ca. 5 μm, after which a conductor pattern was etched with the help of a familiar photo-etching method. A Teflon laminate with etched slots was then glued to the resulting distribution network with the help of thermoplastic adhesive.

The antenna produced in this way with the dimensions 50×50 mm has been found on measurement to achieve largely the same electrical properties as a waveguide slot antenna with the dimensions 150×150 mm.

Illustrated on the left in FIG. 1 is the etched conductor pattern 1 in the intended antenna 2, while the telephone laminate 3 with slots 4 is illustrated on the right in FIG. 1.

### EXAMPLE 2

An aluminium sheet with the dimensions 2×35×35 mm was hard anodized in an electrolyte that was doped with barium titanate in the following way:

Barium titanate in solid form was dissolved in hot concentrated sulphuric acid, which, after being allowed to cool to room temperature, was diluted with deionized water in a proportion of 20 per cent by weight. The barium titanate is then precipitated in the form of a fine-grained precipitate. This mixture is then used as an electrolyte, in conjunction with which compressed air is used to keep the precipitate in dispersion. An antenna was otherwise produced in the same way as in the above example.

The invention is naturally not restricted to the embodiment described above and illustrated in the accompanying drawing. Modifications are possible, in particular with regard to the nature of the different parts, or by the use of equivalent technology, without departing from the area of protection afforded to the invention as defined in the Patent Claims.

1. Process to reduce the dimensions of mechanical components intended for microwave applications, such as antennae (2), power dividers, filters, directional couplers and other integrated line networks, by the introduction of a dielectric with a given dielectric ratio at the actual wavelength characterized in that the mechanical component of the kind in question is made of aluminium, in that use is made of a dielectric consisting of aluminium oxide, which is produced by oxidation of the aluminium in said mentioned aluminium material and in that the electric function is achieved by the application of a metal coating to the formed oxide layer, for example with copper, and by the subsequent etching of the actual conductor pattern.

2. Process in accordance with Patent claim 1, characterized in that use is made of dispersion of a substance with a very high dielectric constant in the electrolyte used for hard anodization in order further to increase the dielectric constant of the oxide layer.

3. Process in accordance with one or other of Patent claims 1-2, characterized in that the oxide layer is produced by hard anodization.

4. Process in accordance with Patent claim 2, characterized in that a substance with a high dielectric constant, which contains barium titanate, is utilized.

5. Process in accordance with one or other of Patent claims 2-3, characterized in that the dispersion used for hard anodization is produced by dissolving substances with a very high dielectric constant in hot concentrated sulphuric acid and by then diluting with water

6. Process in accordance with one or other of Patent claims 1-3, characterized in that a metal coating that consists of copper is utilized.

7. Process in accordance with one or other of Patent claims 1-3, characterized in that vacuum vaporization is used as the coating method.

8. Process in accordance with one or other of the above Patent Claims, characterized in that a thickness of the oxide layer that is at least ca. 50 μm is utilized.

9. Process in accordance with Patent claim 8, characterized in that a thickness of the oxide layer that is 80-100 μm is utilized.
